(19) United States
(12) Patent Application Publication
(10) Pub. No.: US 2024/0074165 A1
(43) Pub. Date: Feb. 29, 2024

(54) SEMICONDUCTOR DEVICE AND METHOD FOR FABRICATING THE SAME

(71) Applicant: SK hynix Inc., Gyeonggi-do (KR)

(72) Inventors: Dae Won KIM, Gyeonggi-do (KR); Yu Ri KIM, Gyeonggi-do (KR); Tae Kyun KIM, Gyeonggi-do (KR); Jin Hwan JEON, Gyeonggi-do (KR); Dong Goo CHOI, Gyeonggi-do (KR); Ri CHOI, Gyeonggi-do (KR)

(21) Appl. No.: 18/194,654

(22) Filed: Apr. 3, 2023

(30) Foreign Application Priority Data
Aug. 31, 2022 (KR) 10-2022-0110094

(51) Int. Cl. H10B 12/00

(52) U.S. Cl. CPC H10B 12/50; H10B 12/09; H10B 12/315; H10B 12/34; H10B 12/482; H10B 12/485

(57) ABSTRACT

A semiconductor device comprises a substrate including first and second regions; a plurality of conductive line structures disposed over the substrate; a plurality of conductive contact plugs formed between the conductive line structures disposed over the first region of the substrate; and a plurality of dummy dielectric plugs disposed over the second region of the substrate.

### CROSS-REFERENCE TO RELATED APPLICATIONS

The present application claims priority to Korean Patent Application No. 10-2022-0110094, filed on Aug. 31, 2022, which is incorporated herein by reference in its entirety.

### BACKGROUND

### 1. Field

The present invention relates generally to semiconductor technology and, more particularly, to a semiconductor device and a method of making the semiconductor device.

### 2. Description of the Related Art

Higher down-scaling of electronic devices requires higher degrees of integration and less space for the various components and between the various components of the semiconductor devices. These requirements present significant challenges for the designer of semiconductor devices and require the development of new ways for manufacturing the semiconductor devices for ensuring the electrical reliability of the various components of the semiconductor devices including adequate electrical connection or separation between adjacent structures as may be needed.

### SUMMARY

Various embodiments of the present invention provide a semiconductor device with improved reliability and a method of fabricating the same.

According to an embodiment of the present invention, a semiconductor device comprises: a substrate including first and second regions; a plurality of conductive line structures disposed over the substrate; a plurality of conductive contact plugs formed between the conductive line structures disposed over the first region of the substrate; and a plurality of dummy dielectric plugs disposed over the second region of the substrate.

According to an embodiment of the present invention, a method of manufacturing a semiconductor device comprises: forming a plurality of conductive line structures over a substrate; forming a line-shaped opening between the conductive line structures; filling a first gap-fill layer in the line-shaped openings; exposing the first gap-fill layer to post-processing to form a void-free first gap-fill layer; forming a second gap-fill layer over the void-free first gap-fill layer; planarizing the second gap-fill layer to form line patterns which are parallel to the conductive line structures; forming a plurality of contact plugs and a plurality of isolation grooves by etching the line patterns; filling a plug isolation layer in the plurality of isolation grooves; and recessing the contact plugs to form recessed contact plugs. The void-free first gap-fill layer and the second gap-fill layer may include polysilicon. The post-processing may include laser annealing. The forming of the line-shaped opening between the conductive line structures may include forming a multi-layered spacer layer between the conductive line structures. The forming of the plurality of contact plugs and the plurality of isolation grooves by etching the line patterns may include forming a mask layer extending in a perpendicular direction to the line patterns; and etching the line patterns using the mask layer.

According to an embodiment of the present invention, a method of manufacturing a semiconductor device comprises: forming a plurality of conductive line structures over a substrate, the substrate including first and second regions; forming line patterns between the conductive line structures; forming a plurality of contact plugs disposed in the first region and a plurality of dummy plugs disposed in the second region by etching the line patterns; filling plug isolation layers in the plurality of contact plugs; forming a plurality of dummy grooves by removing the plurality of dummy plugs in the second region; and forming dummy dielectric plugs filling the plurality of the dummy grooves. The forming of the line patterns may include forming a line-shaped opening between the conductive line structures; filling a first gap-fill layer in the line-shaped opening; exposing the first gap-fill layer to post-processing to form a void-free first gap-fill layer; forming a second gap-fill layer over the void-free first gap-fill layer; and planarizing the second gap-fill layer to form line patterns parallel to the conductive line structures. The void-free first gap-fill layer and the second gap-fill layer include polysilicon. The post-processing may include laser annealing.

Since the present disclosure proceeds in the order of deposition, laser annealing, deposition, and planarization when forming a contact plug, a void-free contact plug may be formed.

These and other features and advantages of the present invention will be better understood from the following detailed description of specific embodiments of the present invention in conjunction with the following drawings.

### BRIEF DESCRIPTION OF THE FIGURES

FIGS. 1A to 1M are plan views illustrating a method of manufacturing a semiconductor device according to an embodiment of the present invention.

FIGS. 2A to 2M are cross-sectional views illustrating a method of manufacturing the semiconductor device taken along line A-A′ of FIGS. 1A to 11.

FIG. 3A is a plan view illustrating a semiconductor device according to an embodiment of the present invention.

FIG. 3B is a cross-sectional view taken along line A-A′ of FIG. 3A.

FIGS. 4A to 4P are diagrams illustrating an example of a method of manufacturing a semiconductor device according to an embodiment of the present invention.

### DETAILED DESCRIPTION

Embodiments described herein will be described with reference to cross-sectional, plan and block diagrams, which are ideal schematic diagrams of the present invention. Accordingly, the shapes shown in the illustrative drawings may be modified due to fabricating technology and/or tolerance. Accordingly, the embodiments of the present invention are not limited to the specific shapes shown, but may also include changes in the shapes caused by the fabricating process. Accordingly, the regions illustrated in the drawings have schematic properties, and the shapes of the regions illustrated in the drawings are intended to illustrate specific shapes of regions of the device, and not to limit the scope of the invention.

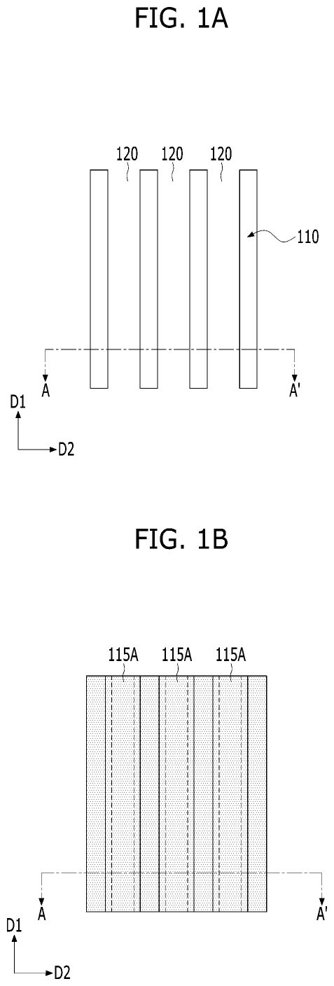

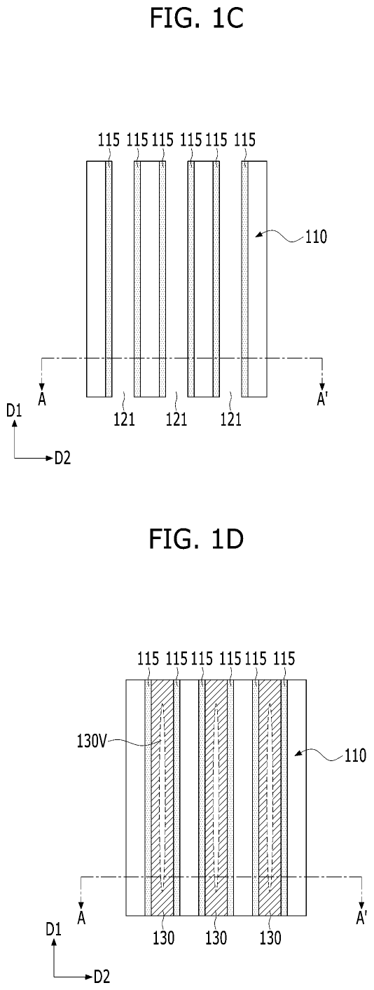

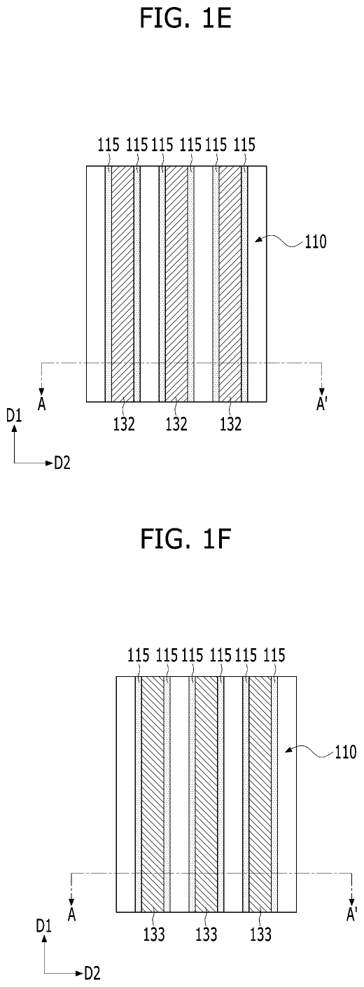

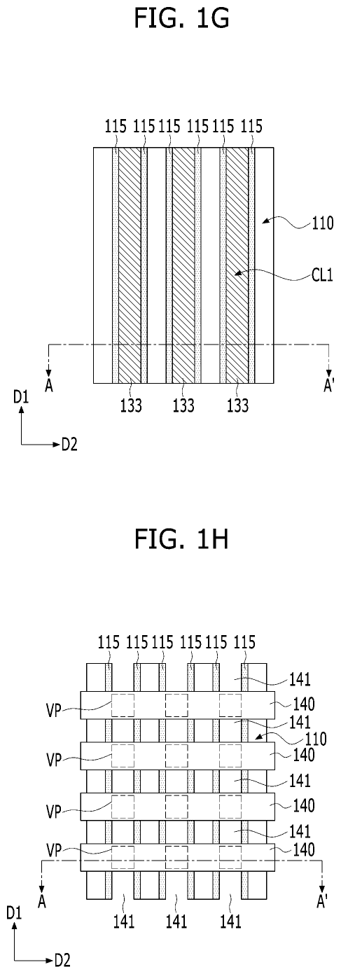

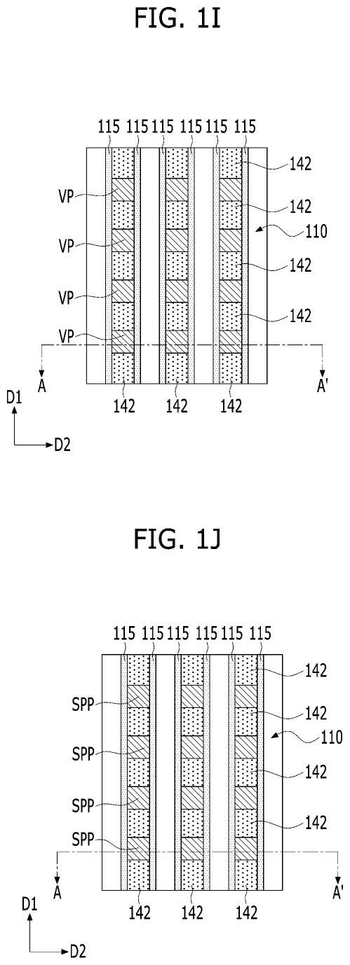

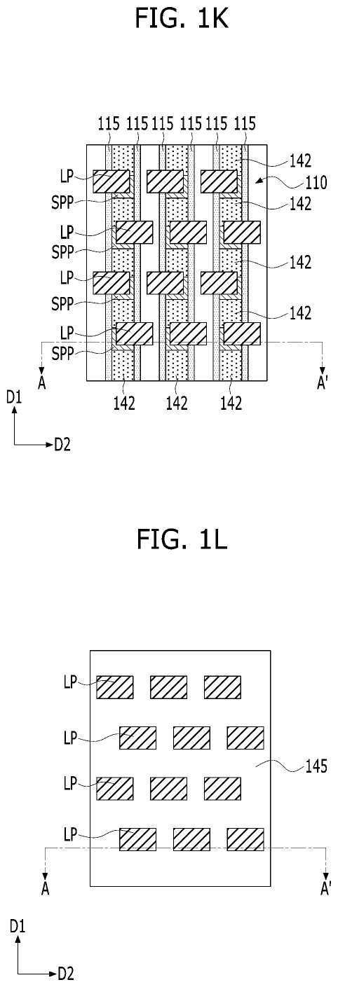

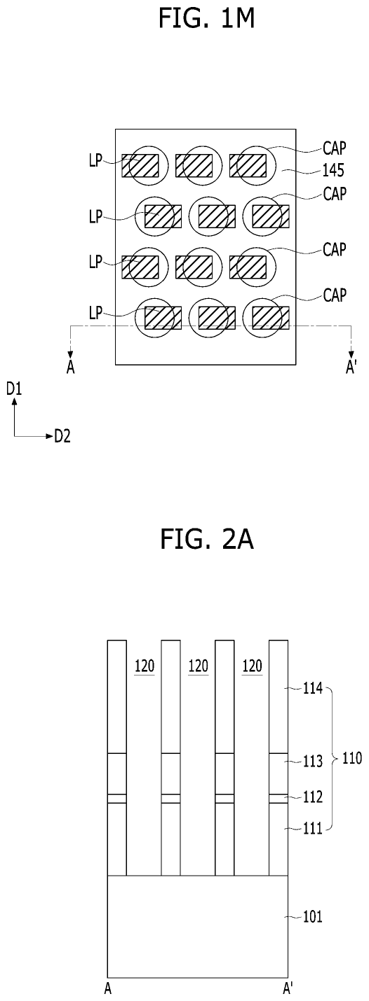

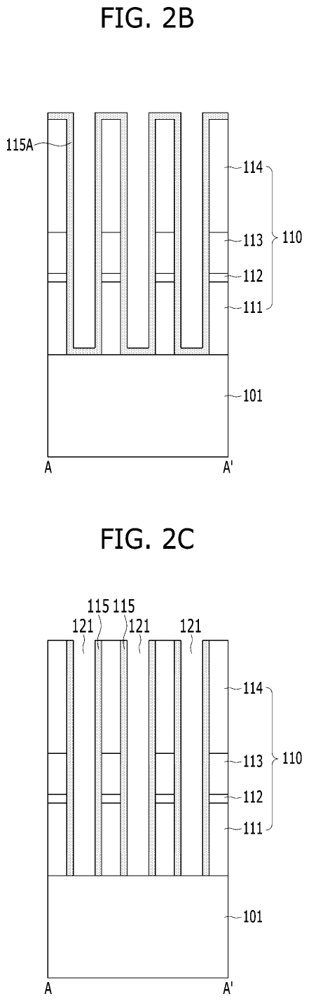

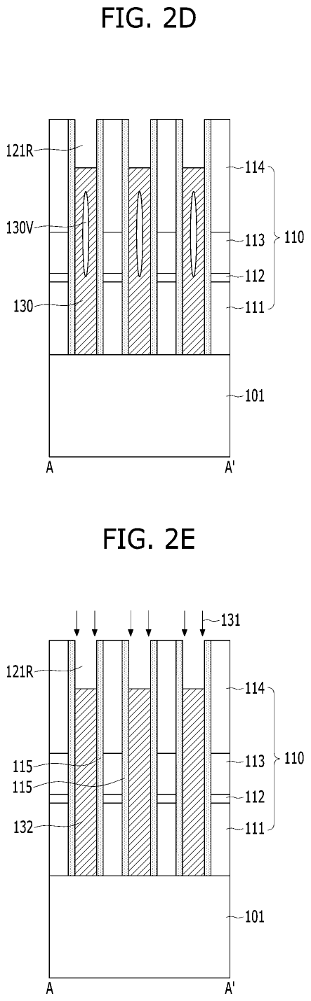

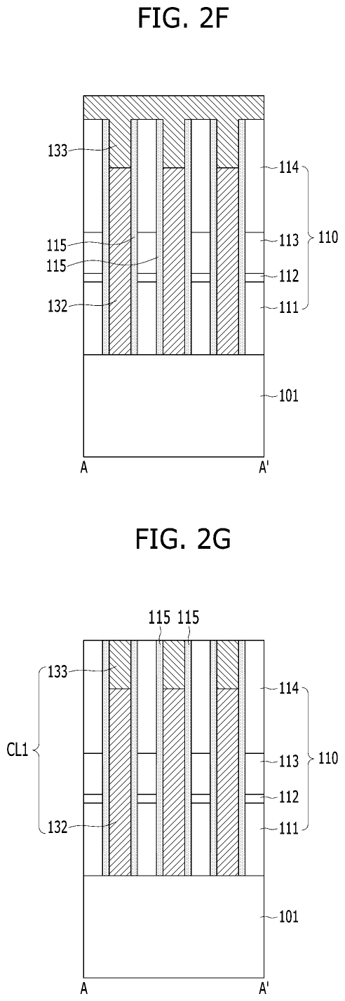

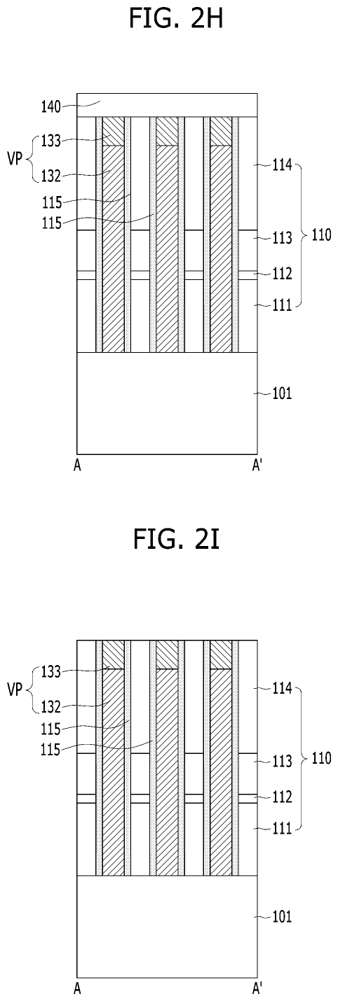

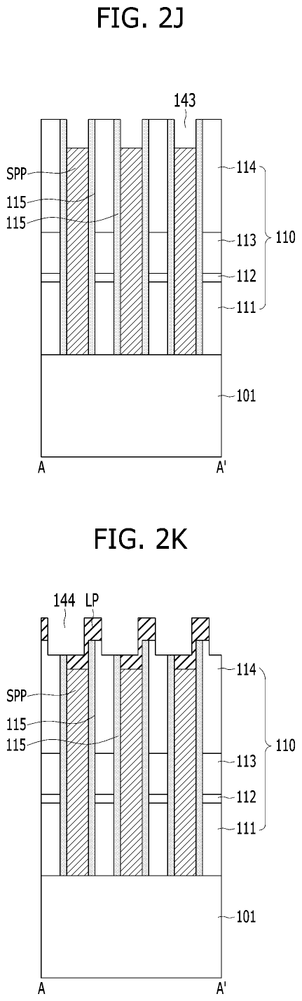

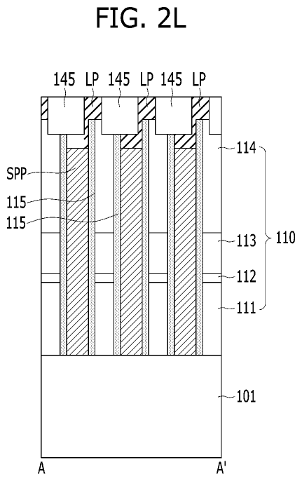

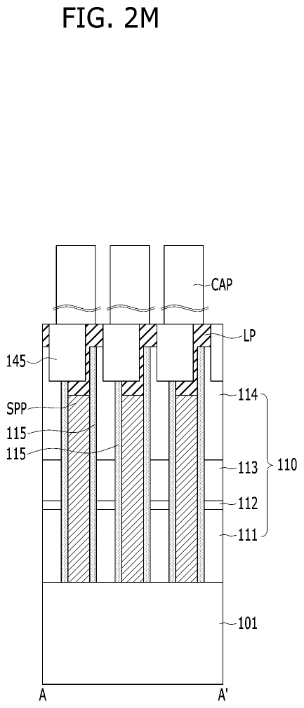

As shown in FIGS. 1A and 2A, a plurality of conductive line structures 110 may be formed on the substrate 101 and the line-shaped openings 120 may be formed between the conductive line structures 110. The conductive line structures 110 may extend along the first direction D1 above the substrate 101. The individual conductive line structures 110 may be stacked in the order of a first plug 111, a barrier layer 112, a conductive line 113, and a capping layer 114. The first plug 111, the barrier layer 112, and the conductive line 113 may include a conductive material. The first plug 111, the barrier layer 112, and the conductive line 113 may include polysilicon, a metal-based material, or a combination thereof. In an embodiment, the metal-based material may include a metal, a metal nitride, or a metal silicide. For example, the first plug 111 may be made of polysilicon, the barrier layer 112 may be made of metal nitride, and the conductive line 113 may be made of metal. The barrier layer 112 and the conductive line 113 may include titanium nitride and tungsten, respectively.

As shown in FIGS. 1B and 2B, a spacer layer 115A may be formed on the conductive line structures 110. The spacer layer 115A may include a dielectric material. The spacer layer 115A may include silicon oxide, silicon nitride, or a combination thereof.

As shown in FIGS. 1C and 2C, the spacer layer 115A may be etched to form spacers 115. The spacers 115 may be formed on both sidewalls of the conductive line structures 110. The line-shaped openings 120 may be narrowed by the spacers 115 and form narrower line-shaped openings indicated by reference numerals 121.

As shown in FIGS. 1D and 2D, a first gap-fill layer 130 filling the line-shaped openings 121 may be formed. The first gap-fill layer 130 may include a conductive material such as, for example, polysilicon. The first gap-fill layers 130 may include a void 130V or a seam. The first gap-fill layers 130 may partially fill the respective spaces between the conductive line structures 110. Small aspect ratio features 121R may be provided over the respective first gap-fill layers 130. The small aspect ratio features 121R may be defined over the respective first gap-fill layers 130 after partially filling the line-shaped openings 121 with the first gap-fill layers 130.

As shown in FIGS. 1E and 2E, annealed first gap-fill layers 132 may be formed. The annealed first gap-fill layers 132 may be formed by performing post-processing 131 on the first gap-fill layers 130. The post-processing 131 may include, for example, laser annealing. Laser annealing may include annealing using a melt laser. The annealed first gap-fill layers 132 may not include a void 130V or a seam. The voids 130V of the first gap-fill layers 130 may be removed by the post-processing 131. The annealed first gap-fill layers 132 may include annealed polysilicon. The annealed first gap-fill layers 132 may be disposed between the conductive line structures 110 and may extend in the first direction D1. That is, the annealed first gap-fill layers 132 may each have a line shape. The conductive line structures 110 and the annealed first gap-fill layers 132 may be parallel to each other in the first direction D1. The conductive line structures 110 and the annealed first gap-fill layers 132 may be alternately disposed along the second direction D2. The annealed first gap-fill layers 132 may be referred to as a ‘void-free first gap-fill layers’.

As shown in FIGS. 1F and 2F, a second gap-fill layer 133 may be formed on each of the annealed first gap-fill layer 132. The second gap-fill layers 133 and the annealed first gap-fill layers 132 may be formed of the same material. The second gap-fill layers 133 may include a conductive material such as, for example, polysilicon. The second gap-fill layers 133 may not include a void or a seam. The small aspect ratio features 121R on top of the respective annealed first gap-fill layer 132 may be filled with the respective second gap-fill layer 133 without voids. The second gap-fill layers 133 may be referred to as a non-annealed second gap-fill layers.

As shown in FIGS. 1G and 2G, planarization may be performed on the second gap-fill layers 133. For the planarization of the second gap-fill layers 133, etch-back or chemical mechanical polishing (CMP) may be applied.

By planarizing the second gap-fill layers 133, preliminary conductive line structures CL1 may be formed between the conductive line structures 110. The preliminary conductive line structures CL1 may be stacked in the order of the annealed first gap-fill layer 132 and the second gap-fill layer 133.

As shown in FIGS. 1H and 2H, a mask layer 140 may be formed on the preliminary conductive line structures CL1. The mask layer 140 may include a photoresist pattern. The mask layer 140 may extend along the second direction D2 crossing the conductive line structures 110 and the preliminary conductive line structures CL1.

The preliminary conductive line structures CL1 may be selectively etched using the mask layer 140 and the conductive line structures 110. Accordingly, pillar structures VP may be formed. The pillar structures VP may be stacked in the order of the annealed first gap-fill layer 132 and the second gap-fill layer 133. Vertical openings 141 may be defined between the pillar structures VP.

As shown in FIGS. 1I and 2I, the mask layer 140 may be removed.

After removing the mask layer 140, plug isolation layers 142 filling the vertical openings 141 may be formed. The plug isolation layers 142 may include a dielectric material. The plug isolation layers 142 may include silicon oxide, silicon nitride, a low-k material, or a combination thereof. The plug isolation layers 142 and the pillar structures VP may be alternately disposed along the first direction D1.

According to the above-described embodiment, the pillar structures VP may be disposed between the conductive line structures 110, and the plug isolation layers 142 may be disposed between the pillar structures VP.

As shown in FIGS. 1J and 2J, upper portions of the pillar structures VP may be selectively recessed. Accordingly, recessed pillar structures SPP may be formed. An etch-back process of the second gap-fill layer 133 may be performed to form the recessed pillar structures SPP. In another embodiment, after all of the second gap-fill layer 133 is removed through an etch back process, the annealed first gap-fill layer 132 may be partially etched back. The recessed pillar structures SPP may have a double structure of the annealed first gap-fill layer 132 and the second gap-fill layer 133, or a single structure of the annealed first gap-fill layer 132.

As shown in FIGS. 1K and 2K, landing pads LP may be respectively formed on the recessed pillar structures SPP. Pad trenches 144 may be defined between the landing pads LP. The landing pads LP may include a conductive material such as metal.

As illustrated in FIGS. 1L and 2L, pad isolation layers 145 filling the pad trenches 144 may be formed. The pad isolation layers 145 may include silicon oxide, silicon nitride, boron nitride, silicon carbon nitride, or a combination thereof.

As shown in FIGS. 1M and 2M, a memory element CAP may be formed on the landing pads LP. The memory element CAP may include a capacitor.

In the above-described embodiment, the pillar structures SPP may be referred to as storage node contact plugs, and the conductive line structures 110 may be referred to as bit line structures.

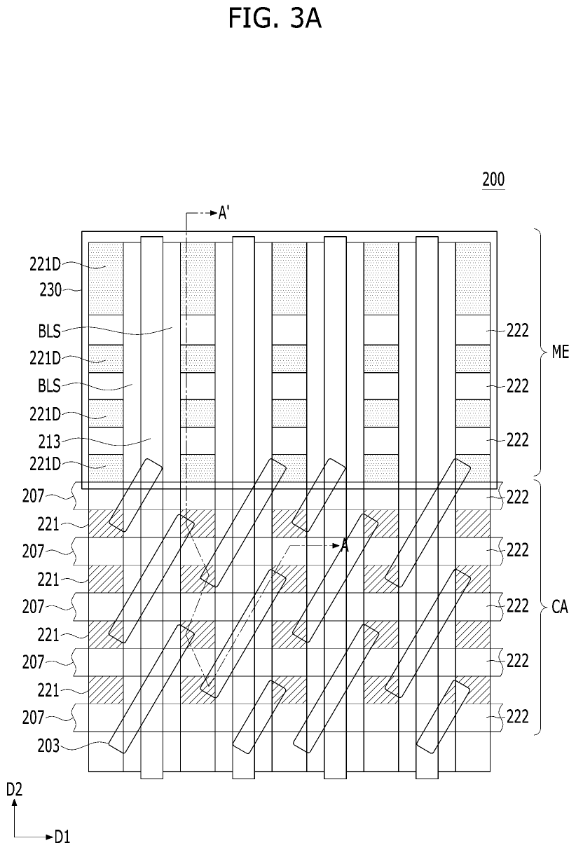

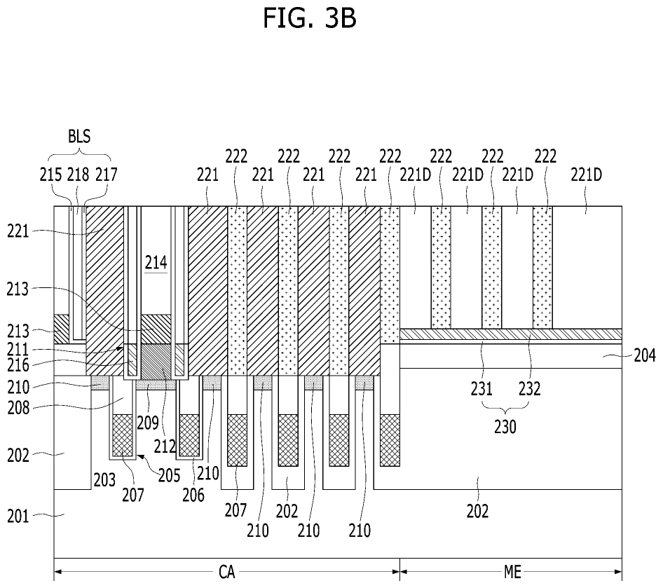

FIG. 3A is a plan view illustrating a semiconductor device according to an embodiment. FIG. 3B is a cross-sectional view taken along line A-A′ of FIG. 3A.

Referring to FIGS. 3A and 3B, the semiconductor device 200 may include a plurality of memory cells. Each memory cell may include a cell transistor including a buried word line 207 and a bit line 213.

The semiconductor device 200 will be described in detail.

A device isolation layer 202 and an active region 203 may be formed on the substrate 201. A plurality of active regions 203 may be defined by the device isolation layers 202. The substrate 201 may be formed of a material suitable for semiconductor processing. The substrate 201 may include a semiconductor substrate. The substrate 201 may be made of a material containing silicon. The substrate 201 may include silicon, monocrystalline silicon, polysilicon, amorphous silicon, silicon germanium, monocrystalline silicon germanium, polycrystalline silicon germanium, carbon doped silicon, combinations thereof, or multiple layers thereof. The substrate 201 may include other semiconductor materials such as germanium. The substrate 201 may include a III/V group semiconductor substrate, for example, a compound semiconductor substrate such as GaAs. The substrate 201 may include a silicon on insulator (SOI) substrate. The device isolation layer 202 may be formed by a shallow trench isolation (STI) process.

A gate trench 205 may be formed in the substrate 201. A gate dielectric layer 206 is formed on the surface of the gate trench 205. A buried word line 207 may be formed on the gate dielectric layer 206 to partially fill the gate trench 205. A gate capping layer 208 may be formed on the buried word line 207. The upper surface of the buried word line 207 may be at a lower level than the surface of the substrate 201. The buried word line 207 may be made of a low-resistivity metallic material. In the buried word line 207, titanium nitride and tungsten may be sequentially stacked. In another embodiment, the buried word line 207 may be formed of titanium nitride only (TiN only). The buried word line 207 may be referred to as a ‘buried gate electrode’. The buried word line 207 may extend long in the first direction D1.

First and second impurity regions 209 and 210 may be formed in the substrate 201. The first and second impurity regions 209 and 210 may be spaced apart from each other by the gate trench 205. The first and second impurity regions 209 and 210 may be referred to as source/drain regions. The first and second impurity regions 209 and 210 may include N-type impurities such as arsenic (As) or phosphorus (P). Accordingly, the buried word line 207 and the first and second impurity regions 209 and 210 may be cell transistors. The cell transistor may improve the short channel effect by the buried word line 207.

A bit line contact plug 212 may be formed on the substrate 201. The bit line contact plug 212 may be connected to the first impurity region 209. The bit line contact plug 212 may be disposed in the bit line contact hole 211. The bit line contact hole 211 may extend to the substrate 201 through the hard mask layer 204. The hard mask layer 204 may be formed on the substrate 201. The hard mask layer 204 may include a dielectric material. The bit line contact hole 211 may expose the first impurity region 209. A lower surface of the bit line contact plug 212 may be at a lower level than upper surfaces of the device isolation layer 202 and the active region 203. The bit line contact plug 212 may be formed of polysilicon or a metal material. A portion of the bit line contact plug 212 may have a line width smaller than a diameter of the bit line contact hole 211. A bit line 213 may be formed on the bit line contact plug 212. A bit line hard mask 214 may be formed on the bit line 213. The stacked structure of the bit line contact plug 212, the bit line 213, and the bit line hard mask 214 may be referred to as a bit line structure. The bit line 213 may have a line shape extending in the second direction D2 crossing the buried word line 207. A portion of the bit line 213 may be connected to the bit line contact plug 212. The bit line 213 and the bit line contact plug 212 may have the same line width in the first direction. Accordingly, the bit line 213 may extend in the second direction D2 while covering the bit line contact plug 212. The bit line 213 may include a metal material such as tungsten. The bit line hard mask 214 may include a dielectric material such as silicon nitride.

A spacer structure BLS may be formed on a sidewall of the bit line structure. The spacer structure BLS may extend to be disposed on a sidewall of the bit line contact plug 212. For example, the spacer structure BLS on both sidewalls of the bit line 213 may include a first spacer 215, a second spacer 217, and a third spacer 218. The spacer structure BLS adjacent to the bit line contact plug 212 may include a first spacer 215 and a gap-fill spacer 216. The spacer structure BLS may include silicon nitride, silicon oxide, a low-k material, or a combination thereof. The low-k material may include SiBN, SiCO, SiCN, SiBCN, or a combination thereof. The first spacer 215 and the gap-fill spacer 216 may include silicon nitride, and the second spacer 217 may include silicon oxide or a low-k material. In another embodiment, the spacer structure BLS may include a multi-layered spacer. For example, it may include NKON, NKNAN, NKOK, NKOKN, NKAKN, KOK or KAK, where N refers to silicon nitride, K refers to a low-k material, O refers to silicon oxide, and A refer to an air gap. In another embodiment, the outermost spacer of the spacer structure BLS may include a low-k material.

A storage node contact plug 221 may be formed between adjacent bit line structures. The storage node contact plug 221 may be connected to the second impurity region 210. The storage node contact plug 221 may include polysilicon, metal nitride, a metal material, metal silicide, or a combination thereof. In some embodiments, the storage node contact plug 221 may be stacked in the order of polysilicon, cobalt silicide, and tungsten.

When viewed from a direction parallel to the bit line structure, plug isolation layers 222 may be formed between adjacent storage node contact plugs 221. The plug isolation layers 222 may be formed between adjacent bit line structures. The storage node contact plugs 221 adjacent in the second direction D2 may be spaced apart by the plug isolation layers 222. A plurality of plug isolation layers 222 and a plurality of storage node contact plugs 221 may be alternately disposed between adjacent bit line structures in the second direction D2. The storage node contact plug 221 may directly contact the third spacer 218 of the spacer structure BLS, and the third spacer 218 may include a low-k material.

A memory element may be formed on the storage node contact plug 222. The memory element may include a capacitor comprising a storage node. The storage node may include a pillar type. A dielectric layer and a plate node may be further formed on the storage node. The storage node may be a cylinder type in addition to the pillar type.

The plug isolation layer 222 may include silicon nitride or a low-k material. When the plug isolation layer 222 includes a low-k material, parasitic capacitance disposed between the storage node contact plugs 221 adjacent to each other with the plug isolation layer 222 interposed therebetween may be reduced. The plug isolation layer 222 may include SiCO, SiCN, SiOCN, SiBN, or SiBCN.

Referring to FIGS. 3A and 3B, the semiconductor device 200 may include a cell array region CA and a cell array edge region ME. A plurality of storage node contact plugs 221 may be formed in the cell array region CA, and a plurality of dummy dielectric plugs 221D may be formed in the cell array edge region ME. A stopper structure 230 may be disposed under the dummy dielectric plugs 221D. The cell array edge region ME may refer to an edge of the cell array region CA. Also, the cell array edge region ME may refer to a boundary region between the cell array region CA and a peripheral circuit region. The cell array region CA may be a cell mat region, and the cell array edge region ME may be a cell mat edge region.

Bottom surfaces of the storage node contact plugs 221 may be disposed at a lower level than bottom surfaces of the dummy dielectric plugs 221D. The stopper structure 230 may be formed under the dummy dielectric plugs 221D to form a leveling structure with the storage node contact plugs 221. As will be described later, the storage node contact plug 221 and the dummy dielectric plug 221D may be simultaneously formed. For example, after a line-type polysilicon layer is formed in the cell array region CA and the cell array edge region ME, the storage node contact plug 221 and the dummy dielectric plug 221D may be simultaneously formed by etching the line-type polysilicon layer.

As described above, by forming the stopper structure 230 in the cell array edge region ME, the etching difficulty for forming the storage node contact plug 221 and the dummy dielectric plug 221D may be reduced, and etching failure may be prevented.

The stopper structure 230 may be formed of the same material as a portion of the spacer structure BLS. For example, the stopper structure 230 may include silicon nitride, silicon oxide, or a combination thereof. After the spacer structure BLS is formed as a multi-layered structure of silicon nitrides and silicon oxides, silicon nitrides or silicon oxides may be partially left by using a mask layer to form the stopper structure 230. In this embodiment, the stopper structure 230 may include a stack of a first stopper 231 and a second stopper 232. The first stopper 231 and the second stopper 232 may include silicon nitride. The first stopper 231 and the first spacer 215 may be made of the same material, for example, silicon nitride. The second stopper 232 and the gap-fill spacer 216 may be formed of the same material, for example, silicon nitride.

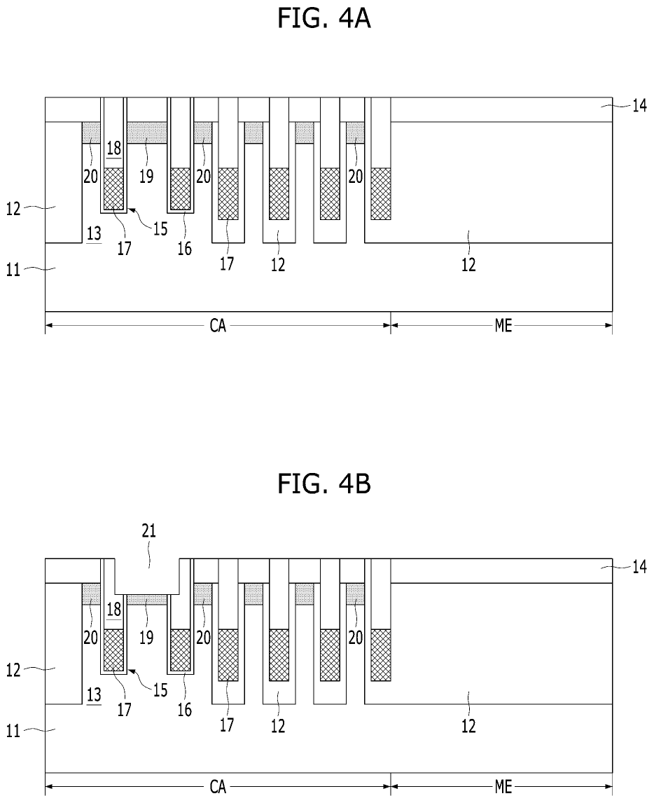

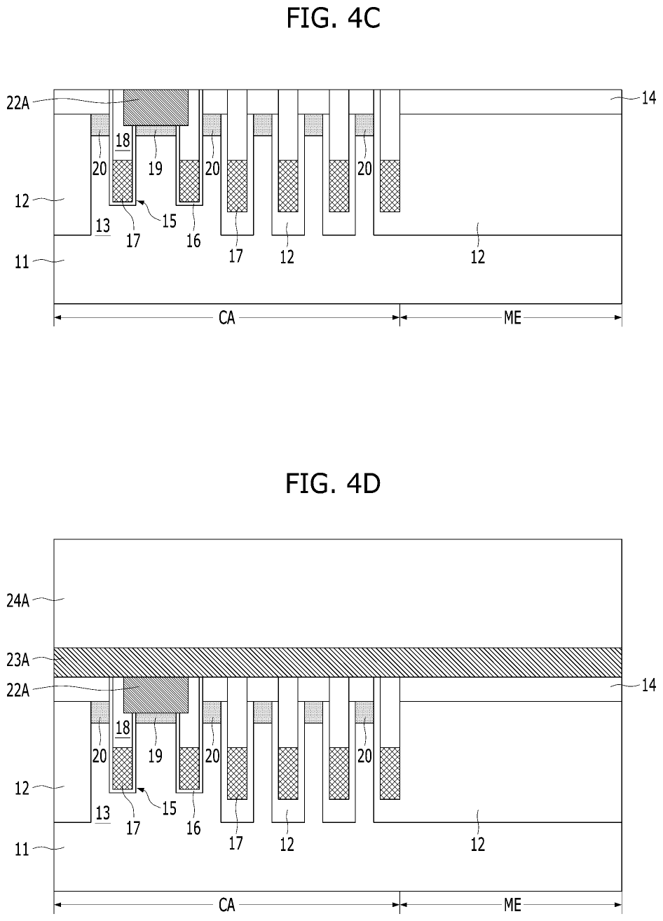

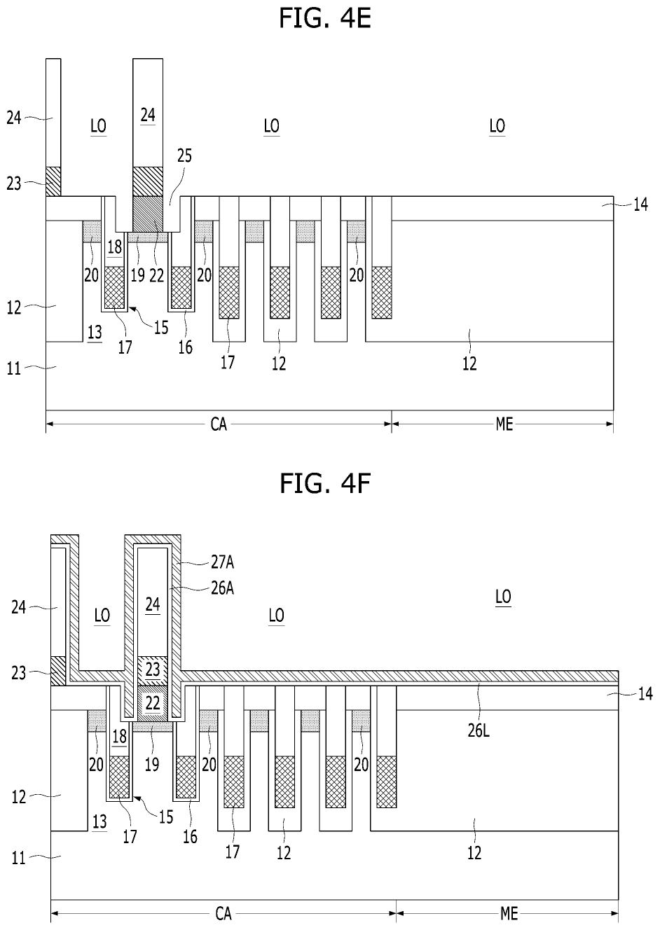

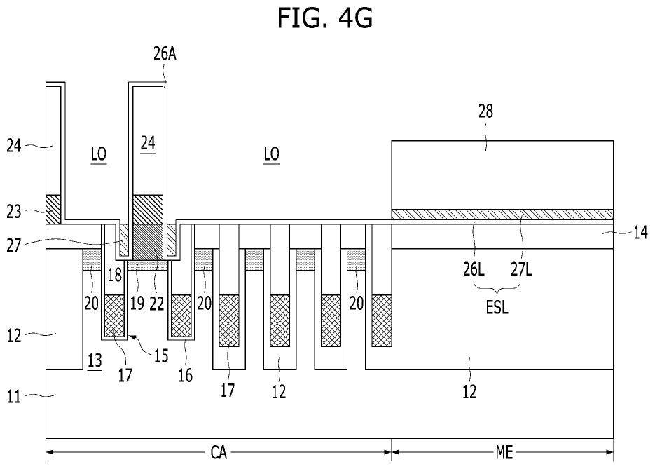

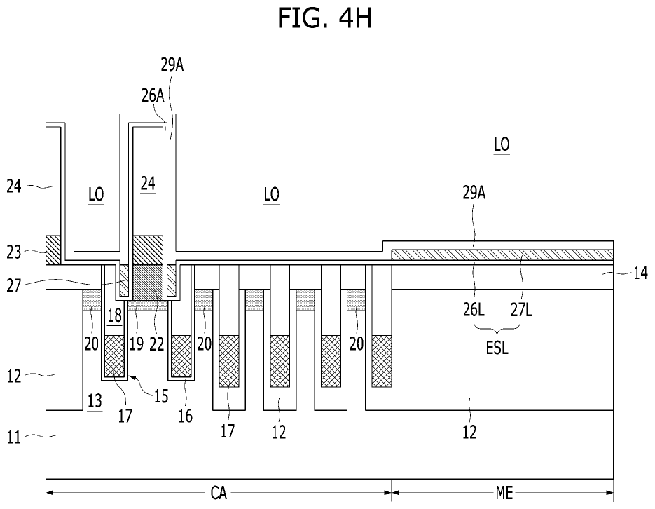

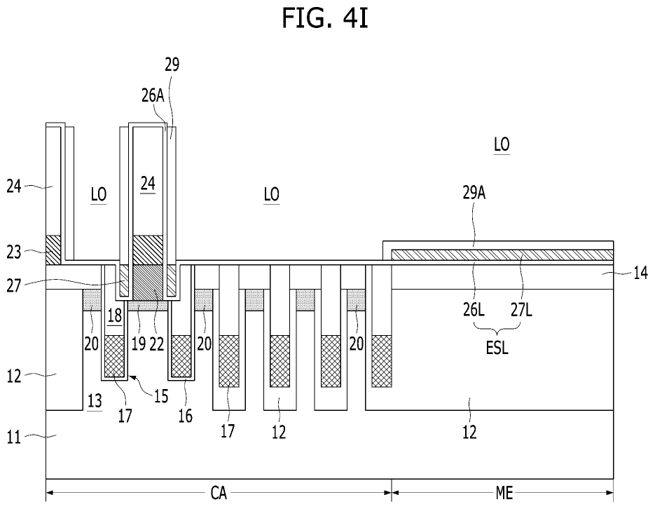

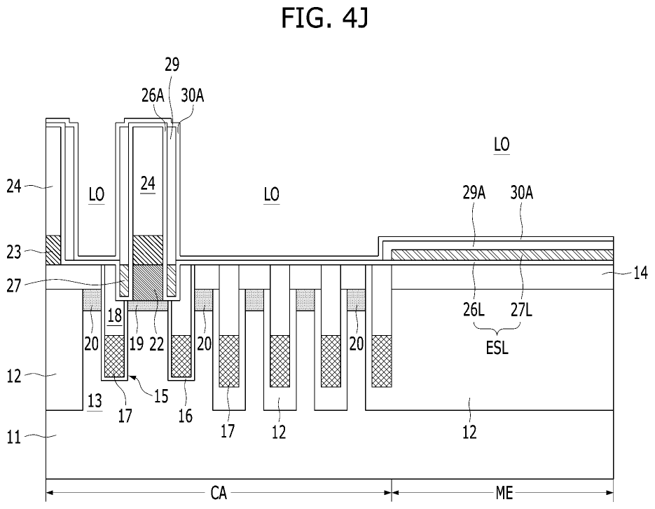

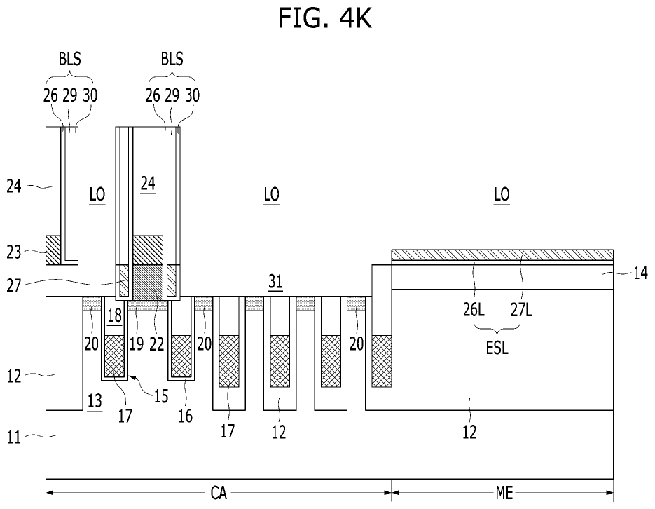

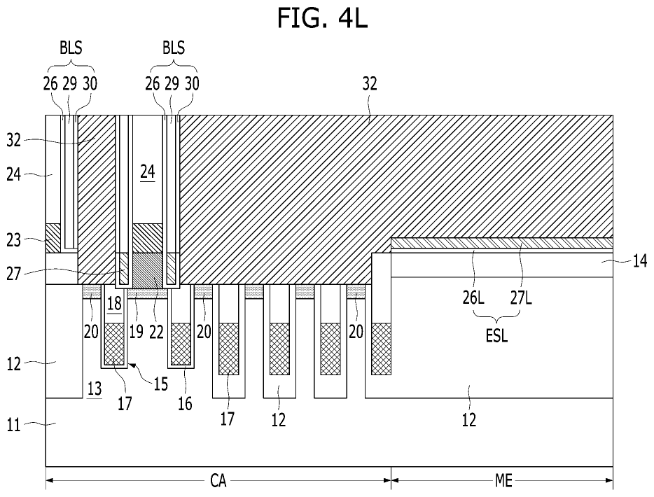

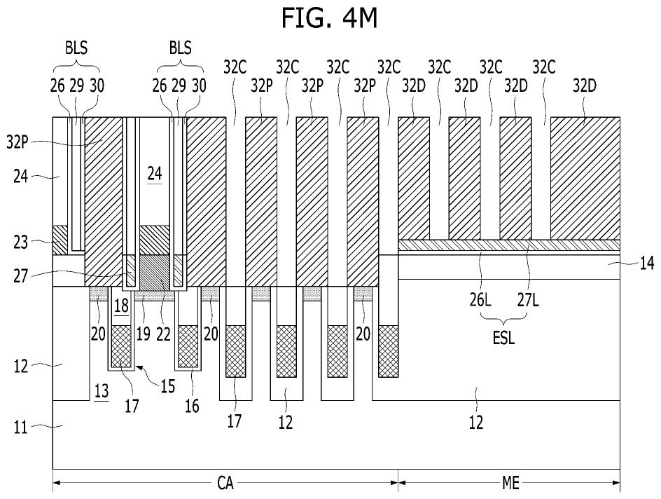

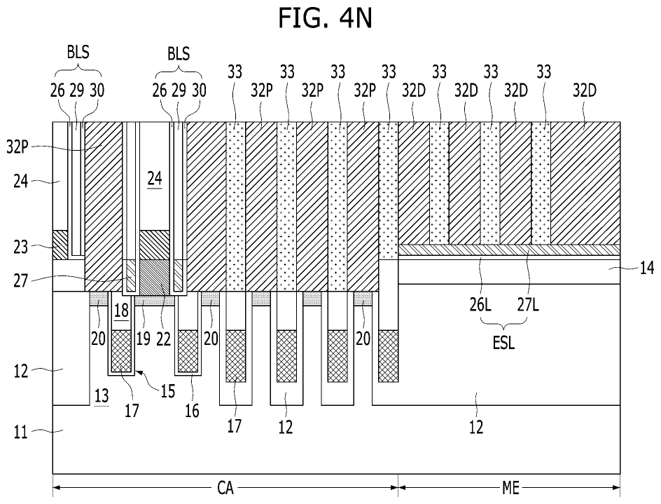

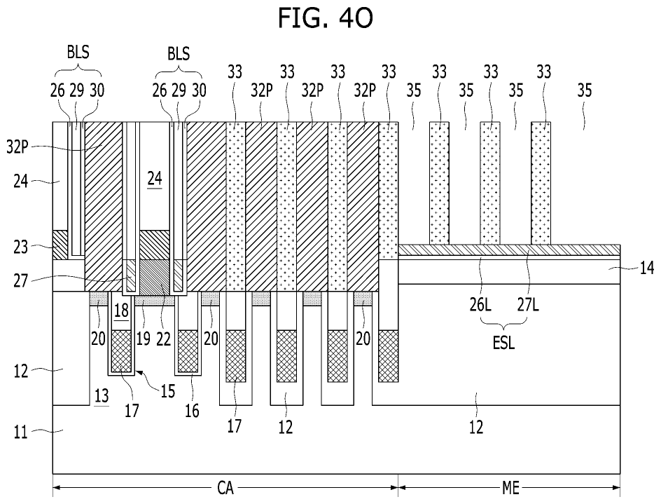

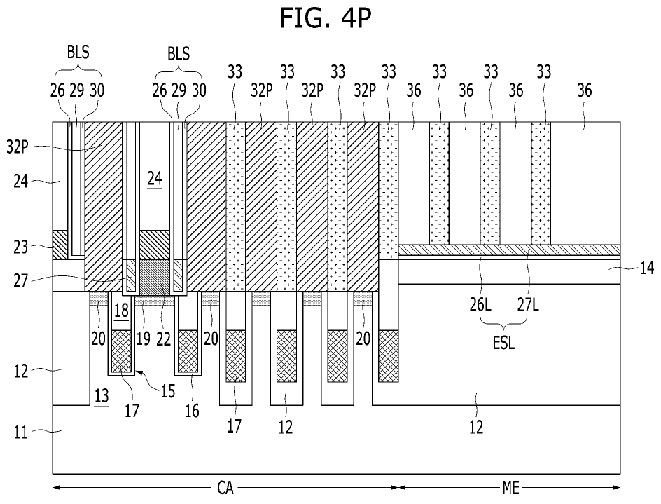

FIGS. 4A to 4P are diagrams illustrating of a method of fabricating a semiconductor device according to an embodiment. FIGS. 4A to 4P illustrate a fabrication method with reference to line A-A′ of FIG. 3A.

As shown in FIG. 4A, a device isolation layer 12 may be formed on the substrate 11. The substrate 11 may include a cell array region CA and a cell array edge region ME. A plurality of active regions 13 are defined by the device isolation layer 12. The device isolation layer 12 may be formed by a shallow trench isolation (STI) process. The STI process is as follows. The substrate 11 is etched to form an isolation trench (reference numeral omitted). The isolation trench is filled with a dielectric material, and thus the device isolation layer 12 is formed. The device isolation layer 12 may include silicon oxide, silicon nitride, or a combination thereof. Chemical vapor deposition (CVD) or other deposition processes may be used to fill the isolation trench with a dielectric material. A planarization process such as chemical-mechanical polishing (CMP) may additionally be used.

Next, a buried word line structure may be formed in the substrate 11. The buried word line structure may include a gate trench 15, a gate dielectric layer 16 covering a bottom surface and sidewalls of the gate trench 15, a buried word line 17 partially filling the gate trench 15 on the gate dielectric layer 16, a gate capping layer 18 formed on the buried word line 17.

A method of forming the buried word line structure is as follows.

First, a gate trench 15 may be formed in the substrate 11. The gate trench 15 may have a line shape crossing the active regions 13 and the device isolation layer 12. The gate trench 15 may be formed by forming a mask pattern on the substrate 11 and an etching process using the mask pattern as an etching mask. To form the gate trench 15, a hard mask layer 14 may be used as an etch barrier. The hard mask layer 14 may have a shape patterned by a mask pattern. The hard mask layer 14 may include silicon oxide. The hard mask layer 14 may include tetra ethyl ortho silicate (TEOS). The bottom of the gate trench 15 may be at a higher level than the bottom of the isolation layer 12.

A portion of the isolation layer 12 may be recessed to protrude the active region 13 under the gate trench 15. For example, the device isolation layer 12 under the gate trench 15 may be selectively recessed along the length direction of the gate trench 15. Accordingly, a fin region (reference numeral omitted) may be formed under the gate trench 15. The fin region may be a part of the channel region.

Next, a gate dielectric layer 16 may be formed on the bottom surface and sidewalls of the gate trench 15. Before forming the gate dielectric layer 16, the etch damage on the surface of the gate trench 15 may be repaired. For example, after the sacrificial oxide is formed by thermal oxidation, the sacrificial oxide may be removed.

The gate dielectric layer 16 may be formed by a thermal oxidation process. For example, the gate dielectric layer 16 may be formed by oxidizing the bottom and sidewalls of the gate trench 15.

In another embodiment, the gate dielectric layer 16 may be formed by a deposition method such as chemical vapor deposition (CVD) or atomic layer deposition (ALD). The gate dielectric layer 16 may include a high-k material, oxide, nitride, oxynitride, or a combination thereof. The high-k material may include a hafnium-containing material. The hafnium-containing material may include hafnium oxide, hafnium silicon oxide, hafnium silicon oxynitride, or a combination thereof. In another embodiment, the high-k material may include lanthanum oxide, lanthanum aluminum oxide, zirconium oxide, zirconium silicon oxide, zirconium silicon oxynitride, aluminum oxide, and combinations thereof.

In another embodiment, the gate dielectric layer 16 may be formed by depositing the liner polysilicon layer and then radically oxidizing the liner polysilicon layer.

In another embodiment, the gate dielectric layer 16 may be formed by forming a liner silicon nitride layer and then radically oxidizing the liner silicon nitride layer.

Next, a buried word line 17 may be formed on the gate dielectric layer 16. To form the buried word line 17, a recessing process may be performed after a conductive layer is formed to fill the gate trench 15. The recessing process may be performed as an etch back process or a chemical mechanical polishing (CMP) process and an etch back process may be sequentially performed. The buried word line 17 may have a recessed shape that partially fills the gate trench 15. That is, the upper surface of the buried word line 17 may be at a lower level than the upper surface of the active region 13. The buried word line 17 may include a metal, a metal nitride, or a combination thereof. For example, the buried word line 17 may be formed of a titanium nitride (TIN), tungsten (W), or titanium nitride/tungsten (TiN/W) stack. The titanium nitride/tungsten (TiN/W) stack may have a structure in which titanium nitride is conformally formed and then the gate trench 15 is partially filled using tungsten. As the buried word line 17, titanium nitride may be used alone, and this may be referred to as the buried word line 17 having a “TiN Only” structure. A double gate structure of a titanium nitride/tungsten (TiN/W) stack and a polysilicon layer may be used as the buried word line 17.

Next, a gate capping layer 18 may be formed on the buried word line 17. The gate capping layer 18 may include a dielectric material. The remaining portion of the gate trench 15 on the buried word line 17 is filled with a gate capping layer 18. The gate capping layer 18 may include silicon nitride. In another embodiment, the gate capping layer 18 may include silicon oxide. In another embodiment, the gate capping layer 18 may have a Nitride-Oxide-Nitride (NON) structure. The upper surface of the gate capping layer 18 may be at the same level with the upper surface of the hard mask layer 14. To this end, a chemical mechanical polishing (CMP) process may be performed when the gate capping layer 18 is formed.

After the gate capping layer 18 is formed, impurity regions 19 and 20 may be formed. The impurity regions 19 and 20 may be formed by a doping process such as implantation. The impurity regions 19 and 20 may include a first impurity region 19 and a second impurity region 20. The first and second impurity regions 19 and 20 may be doped with impurities of the same conductivity type. The first and second impurity regions 19 and 20 may have the same depth. In another embodiment, the first impurity region 19 may be deeper than the second impurity region 20. The first and second impurity regions 19 and 20 may be referred to as source/drain regions. The first impurity region 19 may be a region to be connected to a bit line contact plug, and the second impurity region may be a region to be connected to a storage node contact plug. The first impurity region 19 and the second impurity region 20 may be disposed in different active regions 13. Also, the first impurity region 19 and the second impurity region 20 may be spaced apart from each other by the gate trenches 15 and disposed in each of the active regions 13.

A cell transistor of the memory cell may be formed by the buried word line 17 and the first and second impurity regions 19 and 20.

As shown in FIG. 4B, a bit line contact hole 21 may be formed. The hard mask layer 14 may be etched using a contact mask to form the bit line contact hole 21. The bit line contact hole 21 may have a circle shape or an oval shape when viewed in a plan view. A portion of the substrate 11 may be exposed through the bit line contact hole 21. The bit line contact hole 21 may have a diameter set to a predetermined line width. The bit line contact hole 21 may be formed to expose a portion of the active region 13. For example, the first impurity region 19 may be exposed by the bit line contact hole 21. The bit line contact hole 21 may have a diameter greater than the width of the minor axis of the active region 13. Accordingly, in an etching process for forming the bit line contact hole 21, a portion of the first impurity region 19, the device isolation layer 12, and the gate capping layer 18 may be etched. That is, the gate capping layer 18, the first impurity region 19, and the device isolation layer 12 under the bit line contact hole 21 may be recessed to a predetermined depth. Accordingly, the bottom of the bit line contact hole 21 may be extended into the substrate 11. As the bit line contact hole 21 expands, the upper surface of the first impurity region 19 may be recessed, and the upper surface of the first impurity region 19 may be at a level lower than the upper surface of the active region 13.

As shown in FIG. 4C, a preliminary plug 22A is formed. The preliminary plug 22A may be formed by selective epitaxial growth (SEG). For example, the preliminary plug 22A may include an epitaxial layer doped with phosphorus, for example, SEG SiP. In this way, the preliminary plug 22A may be formed without voids by selective epitaxial growth. In another embodiment, the preliminary plug 22A may be formed by polysilicon layer deposition and a CMP process. The preliminary plug 22A may fill the bit line contact hole 21. The upper surface of the preliminary plug 22A may be at the same level as the upper surface of the hard mask layer 14.

As shown in FIG. 4D, a bit line conductive layer 23A and a bit line hard mask layer 24A may be stacked. A bit line conductive layer 23A and a bit line hard mask layer 24A may be sequentially stacked on the preliminary plug 22A and the hard mask layer 14. The bit line conductive layer 23A includes a metal-containing material. The bit line conductive layer 23A may include a metal, a metal nitride, a metal silicide, or a combination thereof. In this embodiment, the bit line conductive layer 23A may include tungsten (W). In another embodiment, the bit line conductive layer 23A may include a stack of titanium nitride and tungsten (TiN/W). In this case, the titanium nitride may serve as a barrier. The bit line hard mask layer 24A may be formed of a dielectric material having an etch selectivity with respect to the bit line conductive layer 23A and the preliminary plug 22A. The bit line hard mask layer 24A may include silicon oxide or silicon nitride. In this embodiment, the bit line hard mask layer 24A may be formed of silicon nitride.

As shown in FIG. 4E, a bit line structure may be formed. The bit line structure may include a stack of bit line contact plugs 22, bit lines 23 and bit line hard mask 24. The bit line contact plug 22, the bit line 23, and the bit line hard mask 24 may be formed by an etching process using a bit line mask layer.

The bit line hard mask layer 24A and the bit line conductive layer 23A may be etched using the bit line mask layer as an etch barrier. Accordingly, the bit line 23 and the bit line hard mask 24 may be formed. The bit line 23 may be formed by etching the bit line conductive layer 23A. The bit line hard mask 24 may be formed by etching the bit line hard mask layer 24A.

Subsequently, the preliminary plug 22A may be etched with the same line width as the bit line 23. Accordingly, a bit line contact plug 22 may be formed. The bit line contact plug 22 may be formed on the first impurity region 19. The bit line contact plug 22 may interconnect the first impurity region 19 and the bit line 23. The bit line contact plug 22 may be formed in the bit line contact hole 21. A line width of the bit line contact plug 22 is smaller than a diameter of the bit line contact hole 21. Gaps 25 may be defined at both sides of the bit line contact plug 22.

As described above, as the bit line contact plug 22 is formed, a gap 25 is formed in the bit line contact hole 21. This is because the bit line contact plug 22 is etched to be smaller than the diameter of the bit line contact hole 21. The gap 25 is not formed to surround the bit line contact plug 22, but is independently formed on both sidewalls of the bit line contact plug 22. As a result, one bit line contact plug 22 and a pair of gaps 25 are disposed in the bit line contact hole 21, and the pair of gaps 25 are spaced apart by the bit line contact plug 22. A bottom surface of the gap 25 may extend into the device isolation layer 12. The bottom surface of the gap 25 may be at a lower level than the recessed top surface of the first impurity region 19.

A structure in which the bit line contact plug 22, the bit line 23, and the bit line hardmask 24 are stacked in the recited order may be referred to as a bit line structure. When viewed from a top view, the bit line structure may be a line-shaped pattern structure extending in any one direction.

A line-shaped opening LO may be defined between neighboring bit line structures. The line-shaped opening LO may be parallel to the bit line structures. The hardmask layer 14 may be exposed by the line-shaped opening LO. The line-shaped opening LO may extend from the cell array region CA to the cell array edge region ME. The hardmask layer 14 of the cell array edge region ME may also be exposed by the line-shaped opening LO.

As shown in FIG. 4F, a first spacer layer 26A may be formed on the bit line structures. The first spacer layer 26A may cover both sidewalls of the bit line contact plug 22 and both sidewalls of the bit line 23. The first spacer layer 26A may cover both sidewalls and top surfaces of the bit line hard mask 24. The first spacer layer 26A may include a dielectric material. In this embodiment, the first spacer layer 26A may include silicon nitride.

A second spacer layer 27A may be formed on the first spacer layer 26A. The second spacer layer 27A and the first spacer layer 26A may be formed of the same material. The second spacer layer 27A may include silicon nitride. The second spacer layer 27A may be conformally formed on top and side surfaces of the bit line structures on the first spacer layer 26A. The second spacer layer 27A may fill the gap 25 at both sides of the bit line contact plug 22.

A first spacer layer 26A and a second spacer layer 27A may be formed in the cell array edge region ME. For example, the first spacer layer 26A and the second spacer layer 27A may extend from the cell array region CA to the cell array edge region ME.

As shown in FIG. 4G, a mask layer 28 may be formed. The mask layer 28 may mask the cell array edge region ME. The mask layer 28 may include a photoresist pattern. The second spacer layer 27A of the cell array region CA may be selectively exposed by the mask layer 28.

Next, selective etching of the second spacer layer 27A may be performed. For example, the second spacer layer 27A may be trimmed to fill the gap 25 at both sides of the bit line contact plug 22. Accordingly, the second spacer layer 27A may remain in the gap 25 on both sides of the bit line contact plug 22, and the second spacer layer 27A may not remain on the first spacer layer 26A on both sides of the bit line 23. The second spacer layer 27A may remain in the cell array edge region ME.

The remaining second spacer layer filling the gap 25 is abbreviated as a ‘gap-fill spacer 27’, and the second spacer layer remaining in the cell array edge region ME is abbreviated as a ‘stop liner 27L’. A first spacer layer 26A may remain under the stop liner 27L. Hereinafter, the first spacer layer remaining in the cell array edge region ME is denoted by reference numeral ‘26L’. The stack of the first spacer layer 26L remaining in the cell array edge region ME and the stop liner 27L is referred to as a ‘stopper structure (ESL)’. In another embodiment, the stack of the first spacer layer 26L and the stop liner 27L may not remain in the cell array edge region ME. That is, the stopper structure ESL may be omitted from the cell array edge region ME.

As shown in FIG. 4H, after the mask layer 14 is removed, a third spacer layer 29A may be formed on the stop liner 27L. The third spacer layer 29A may include silicon oxide. The third spacer layer 29A may be formed in the cell array region CA and the cell array edge region ME. In the cell array region CA, a third spacer layer 29A may be formed on the first spacer layer 26A, the third spacer layer 29A may be formed on the stop liner 27L in the cell array edge region ME.

As shown in FIG. 4I, the third spacer layer 29A may be etched to form the third spacer 29. An etch-back process of the third spacer layer 29A may be performed to form the third spacer 29. The third spacer 29 may cover an upper portion of the gap-fill spacer 28. The third spacer 29 may be disposed on both sidewalls of the bit line 23 with the first spacer layer 26A interposed therebetween. In the cell array edge region ME, the third spacer layer 29A may remain on the stop liner 27L.

As shown in FIG. 4J, a fourth spacer layer 30A may be formed on the third spacer 29 and the third spacer layer 29A. The fourth spacer layer 30A may include silicon nitride.

As shown in FIG. 4K, the fourth spacer layer 30A may be selectively etched to form the fourth spacer 30 on the sidewall of the line-shaped opening LO.

The materials disposed below the fourth spacer layer 30A may be etched to be self-aligned to the fourth spacer 30. Accordingly, a plurality of recess regions 31 exposing a portion of the active region 13 may be formed between the bit line structures. Anisotropic etching or a combination of anisotropic etching and isotropic etching may be used to form the recess regions 31. For example, the fourth spacer layer 30A and the first spacer layer 26A may be sequentially anisotropically etched between the bit line structures, and then a portion of the exposed active region 13 may be isotropically etched. In another embodiment, the hardmask layer 14 may also be isotropically etched. Portions of the active region 13 and the gate capping layer 18 may be exposed by the recess regions 31.

The recess regions 31 may extend into the substrate 11. During the formation of the recess regions 31, the device isolation layer 12, the gate capping layer 18, and the second impurity region may be recessed to a predetermined depth. A bottom surface of the recess regions 31 may be at a level lower than an upper surface of the bit line contact plug 22. The bottom surfaces of the recess regions 31 may be at a higher level than the bottom surfaces of the bit line contact plug 22. The line-shaped openings LO and the recess regions 31 may be interconnected. A vertical structure of the line-shaped openings LO and the recess regions 31 may be referred to as a ‘storage node contact hole’.

A spacer structure BLS may be formed on a sidewall of the bit line structure by etching the fourth spacer layer 30A and the first spacer layer 26A while the recess regions 31 are formed. The spacer structure BLS may include materials having different dielectric constants.

The spacer structure BLS may include a first spacer 26, a third spacer 29, and a fourth spacer 30. The first spacer 26 may directly contact sidewalls of the bit line contact plug 22 and the bit line 23. The third spacer 29 may cover the first spacer 26, and the fourth spacer 30 may cover the third spacer 29. A first spacer 26 may be disposed between the gap-fill spacer 28 and the bit line contact plug 22. A third spacer 29 may be disposed between the fourth spacer 30 and the first spacer 26.

A first spacer 26, a third spacer 29, and a fourth spacer 30 may be sequentially stacked on sidewalls of the bit line 23. A first spacer 26 and a gap-fill spacer 28 may be stacked on sidewalls of the bit line contact plug 22.

As shown in FIG. 4L, line patterns 32 filling each of the line-shaped openings LO may be formed. The line patterns 32 may fill the line-shaped openings LO and the recess regions 31. The line patterns 32 may contact the second impurity regions 20. The line patterns 32 may be adjacent to the bit line structure. When viewed from a top view, a plurality of line patterns 32 may be disposed between the plurality of bit line structures.

The line patterns 32 may be formed in the cell array region CA and extend to the cell array edge region ME.

A method of forming the line patterns 32 will be described with reference to FIGS. 1A to 1G and 2A to 2G. For example, a series of processes for forming the line patterns 32 may proceed in the order of deposition, laser annealing, deposition, and planarization.

As shown in FIG. 4M, the line patterns 32 may be etched using a mask layer extending in a direction crossing the line patterns 32. Accordingly, a plurality of contact plugs 32P and a plurality of isolation grooves 32C may be formed. When viewed from a top view, a plurality of contact plugs 32P may be disposed between adjacent bit line structures, and the isolation grooves 32C may be disposed between the contact plugs 32P. During etching to form the isolation groove 32C, a leveling structure may be formed by the lower stopper structure ESL. The contact plugs formed in the cell array edge region ME may be abbreviated as a dummy plug 32D. The bottom surfaces of the dummy plugs 32D and the bottom surfaces of the contact plugs 32P may be disposed at different levels. For example, the bottom surfaces of the dummy plugs 32D may be disposed at a higher level than the bottom surfaces of the contact plugs 32P.

As shown in FIG. 4N, the plug isolation layer 33 filling the isolation grooves 32C may be formed. To form the plug isolation layer 33, silicon nitride deposition and chemical mechanical polishing (CMP) may be sequentially performed.

As shown in FIG. 4O, dummy grooves 35 may be formed between the plug isolation layers 33 by removing the dummy plugs 32D. The dummy plugs 32D may be removed by using a mask layer that covers the cell array region CA and exposes the cell array edge region ME.

As shown in FIG. 4P, dummy dielectric plugs 36 filling the dummy grooves 35 may be formed. To form the dummy dielectric plugs 36, silicon nitride deposition and chemical mechanical polishing (CMP) may be sequentially performed. The plug isolation layer 33 and the dummy dielectric plugs 36 may be formed of the same material.

According to the above-described embodiment, a series of processes for forming the storage node contact plug 32P is performed in the order of deposition, laser annealing, deposition, and planarization.

When the dummy plugs 32D are removed from the cell array edge region ME, loss of device isolation layer and the active region may occur in the cell array edge region ME.

In the present embodiment, when the storage node contact plug 32P is formed, deposition, laser annealing, deposition, and planarization are performed in the order of deposition, so that the void-free storage node contact plug 32P may be formed.

The present invention described above is not limited by the above-described embodiments and the accompanying drawings. It should be apparent to those skilled in the art that various changes and modifications may be made within the scope of the technical spirit of the present invention.

What is claimed is:

1. A semiconductor device comprising:
a substrate including first and second regions;
a plurality of conductive line structures disposed over the substrate;
a plurality of conductive contact plugs formed between the conductive line structures disposed over the first region of the substrate; and
a plurality of dummy dielectric plugs disposed over the second region of the substrate.

2. The semiconductor device of claim 1, further including plug isolation layers between the conductive line structures,
wherein the conductive contact plugs and the dummy dielectric plugs are disposed between the plug isolation layers.

3. The semiconductor device of claim 2, wherein the plug isolation layers and the dummy dielectric plugs include a dielectric material.

4. The semiconductor device of claim 2,
wherein the plug isolation layers and the dummy dielectric plugs include silicon nitride, and
wherein the conductive contact plugs include polysilicon.

5. The semiconductor device of claim 1,
wherein bottom surfaces of the dummy dielectric plugs are disposed at a higher level than a bottom surface of the conductive contact plugs.

6. The semiconductor device of claim 1, further including a multi-layered spacer formed on both sidewalls of the conductive line structures.

7. The semiconductor device of claim 1, wherein a top surface of the dummy dielectric plugs is disposed at a higher level than a top surface of the conductive contact plugs.

8. The semiconductor device of claim 1,
wherein the conductive contact plugs include storage node contact plugs, and
the conductive line structures include a bit line.

9. The semiconductor device of claim 1, further including:
landing pads respectively disposed on upper portions of the conductive contact plugs,
memory elements respectively disposed on upper portions of the landing pads, and
pad isolation layers disposed between the landing pads.

10. The semiconductor device of claim 9, wherein the landing pads include metal-based material.

11. The semiconductor device of claim 9, wherein the pad isolation layers include silicon oxide, silicon nitride, silicon carbon nitride, boron nitride, or a combination thereof.
